(19) United States
(12) Patent Application Publication
(10) Pub. No.: US 2012/0211890 A1
(43) Pub. Date: Aug. 23, 2012

(54) METHOD FOR FORMING METAL THIN FILM, SEMICONDUCTOR DEVICE AND MANUFACTURING METHOD THEREOF

(75) Inventors: Shuji AZUMO, Nirasaki City (JP); Yasuhiko KOJIMA, Nirasaki City (JP)

(73) Assignee: TOKYO ELECTRON LIMITED, Tokyo (JP)

(21) Appl. No.: 13/364,722

(22) Filed: Feb. 2, 2012

(30) Foreign Application Priority Data
Feb. 21, 2011 (JP) 2011-034502

(51) Int. Cl. H01L 23/532; H01L 21/768

(52) U.S. Cl. 257/751; 438/660; 438/653; 257/E21.584; 257/E23.161

(57) ABSTRACT

A metal thin film forming method includes depositing a Ti film on an insulating film formed on a substrate and depositing a Co film on the Ti film. The film forming method further includes modifying a laminated film of the Ti film and the Co film on the insulating film to a metal thin film containing Co₃Ti alloy by heating the laminated film in an inert gas atmosphere or a reduction gas atmosphere.

### FIELD OF THE INVENTION

The present invention relates to a method for forming a metal thin film, a semiconductor device having the metal thin film, and a manufacturing method thereof.

### BACKGROUND OF THE INVENTION

In an LSI or an MEMS, although Cu has been conventionally used as a Cu plating seed layer for Cu wiring, studies have been made to use a cobalt film instead of the Cu film in order to improve embedding characteristics. When a cobalt film is used as a plating seed layer, it is expected that the adhesivity to a barrier film made of Ta, TaN or the like can be increased and the reliability of the Cu wiring can be improved (e.g., Japanese Patent Application Publication No. 2006-328526).

The demand for high integration of semiconductor devices and scaling-down of chip sizes accelerates the miniaturization of wiring patterns. When the cobalt film is only used as a single layer, the barrier property against the diffusion of Cu is low and, thus, a barrier film needs to be formed in addition to the plating seed layer. However, in the case of separately forming the plating seed layer and the barrier film, the number of processes is increased. Further, the volume of the total film thickness is increased, thereby hindering the miniaturization of wiring patterns.

Moreover, when the cobalt film is formed as the plating seed layer, stress migration or electromigration develops due to poor wettability to Cu. In addition, a delamination void is generated at the boundary between the Cu wiring and the Co seed layer, and defects such as disconnection and the like may occur.

### SUMMARY OF THE INVENTION

In view of the above, the present invention provides a method for forming a metal thin film as a single layer which functions as a Cu diffusion barrier film and a plating seed layer and has a good adhesivity to Cu. Further, the present invention provides a semiconductor device having the metal thin film formed by the film forming method.

In accordance with one aspect of the present invention, there is provided a metal thin film forming method including: depositing a Ti film on an insulating film formed on a substrate; depositing a Co film on the Ti film; and modifying a laminated film of the Ti film and the Co film on the insulating film to a metal thin film containing Co₃Ti alloy by heating the laminated film in an inert gas atmosphere or a reduction gas atmosphere.

In accordance with another aspect of the present invention, there is provided a metal thin film forming method including: depositing a mixed film containing Ti and

Co on an insulating film formed on a substrate by supplying a Ti-containing material and a Co-containing material together; and modifying the mixed film on the insulating film to a metal thin film containing Co₃Ti alloy by heating the mixed film in an inert gas atmosphere or a reduction gas atmosphere.

In accordance with still another aspect of the present invention, there is provided a semiconductor device including: an insulating film; a metal thin film containing Co₃Ti alloy formed on the insulating film; and a Cu wiring formed on the metal thin film containing Co₃Ti alloy.

### BRIEF DESCRIPTION OF THE DRAWINGS

The above and other objects and features of the present invention will become apparent from the following description of embodiments, given in conjunction with the accompanying drawings, in which: p FIG. 1 shows a schematic configuration of a processing system which can be used for a thin film forming method of the present invention;

FIG. 2 shows a schematic configuration of a process module forming a part of the processing system shown in FIG. 1;

FIG. 3 shows a schematic configuration of another process module of the processing system shown in FIG. 1;

FIG. 4 shows a schematic configuration of still another process module of the processing system shown in FIG. 1.

FIG. 5 is a flowchart showing a sequence of a metal thin film forming method in accordance with a first embodiment of the present invention;

FIG. 6 explains main processes of the metal thin film forming method in accordance with the first embodiment of the present invention;

FIG. 7 is a flowchart showing a sequence of a metal film forming method in accordance with a second embodiment of the present invention;

FIG. 8 shows a schematic configuration of a film forming apparatus which can be used for the metal thin film forming method in accordance with the second embodiment of the present invention;

FIG. 9 explains main processes of the metal thin film forming method in accordance with the second embodiment of the present invention;

FIG. 10 is a cross sectional view of a wafer surface which is used for explaining a process in which the film forming method of the present invention is applied to a damascene process;

FIG. 11 is a cross sectional view of principal parts on a wafer surface having a metal thin film containing Co₃Ti alloy in a process continuously following the process shown in FIG. 10; and

FIG. 12 is a cross sectional view of principal parts on a wafer surface in which a Cu film is buried in a process continuously following the process shown in FIG. 11.

### DETAILED DESCRIPTION OF THE EMBODIMENTS

Hereinafter, embodiments of the present invention will be described in detail with reference to the accompanying drawings which form a part hereof.

### First Embodiment

<Outline of Film Forming Apparatus>

First, a configuration of a film forming apparatus suitable for performing a film forming method of the present invention will be described. First, a processing system which can be used in the present embodiment will be described with reference to FIG. 1. FIG. 1 is a schematic configuration view showing a processing system 200 configured to perform a process for forming a thin film containing Co₂Ti alloy on a substrate, e.g., a semiconductor wafer (hereinafter, simply referred to as a “wafer”).

The processing system 200 shown in FIG. 1 is configured as a cluster tool of a multi-chamber structure including a plurality of (four in FIG. 1) process modules 201A to 201D. The processing system 200 mainly includes the four process modules 201A to 201D, a vacuum side transfer chamber 203 connected to the process modules 201A to 201D via gate valves G1, two load-lock chambers 205a and 205b connected to the vacuum side transfer chamber 203 via gate valves G2, and a loader unit 207 connected to the two load-lock chambers 205a and 205b via gate valves G3, respectively.

(Process Module)

In the present embodiment, the process module 201A is configured to form a Co film on the wafer W; the process module 201B is configured to form a Ti film on the wafer W; and the process modules 201C and 201D are configured to perform heat treatment on the wafer W. The assignment of processes performed by the process modules 201A to 201D is not limited thereto.

(Vacuum Side Transfer Chamber)

Provided in the evacuable vacuum side transfer chamber 203 is a transfer device 209 as a first substrate transfer device for transferring the wafer W between the process modules 201A to 201D and the load-lock chambers 205a and 205b. The transfer device 209 has a pair of transfer arms 211 disposed to face each other. The transfer arms 211 are configured to be extensible/contractible and rotatable on the same rotation axis. Further, forks 213 for mounting and holding wafers W thereon are provided at leading ends of the transfer arms 211. The transfer device 209 transfers the wafers W mounted on the forks 213 between the process modules 201A to 201D or between the process modules 201A to 201D and the load-lock modules 205a and 205b.

(Load-lock Chambers)

Provided in the load-lock chambers 205a and 205b are waiting stages 206a and 206b for mounting thereon wafers W. The load-lock chambers 205a and 205b are configured to be switched between a vacuum state and an atmospheric state. The wafer W is transferred between the vacuum side transfer chamber 203 and an atmospheric side transfer chamber 219 (to be described later) via the waiting stages 206a and 206b of the load-lock chambers 205a and 205b.

(Loader Unit)

The loader unit 207 includes: the atmospheric side transfer chamber 219 where a transfer device 217 as a second substrate transfer device for transferring the wafer W is provided; three load ports LP adjacent to one side of the atmospheric side transfer chamber 219; and an orienter 221, adjacent to another side of the atmospheric side transfer chamber 219, serving as an orientation measurement device for measuring an orientation of the wafer W.

(Atmospheric Side Transfer Chamber)

The atmospheric side transfer chamber 219 having a rectangular cross section when viewed from the top includes a circulation system (not shown) for circulating, e.g., a nitrogen gas or clean air, and a guide rail 223 installed in a longitudinal direction thereof. The transfer device 217 is slidably supported by the guide rail 223. That is, the transfer device 217 is configured to be movable in the X direction along the guide rail 223 by a driving mechanism (not shown). The transfer device 217 includes a pair of transfer arms 225 vertically arranged in two stages. Each of the transfer arms 225 is configured to be extensible/contractible and rotatable. Further, forks 227 for mounting and holding wafers W thereon are provided at leading ends of the transfer arms 225. The transfer mechanism 217 transfers the wafers W mounted on the forks 227 between wafer cassettes CR of the load ports LP, the load-lock chambers 205a and 205b, and the orienter 221.

(Load Port)

The load port LP is configured to mount thereon the wafer cassette CR. The wafer cassette CR is configured to store a plurality of wafers W one on top of another at the same interval to give space therebetween. The orienter 221 includes: a rotation plate 233 rotated by a driving motor (not shown); and an optical sensor 237, positioned at an outer periphery of the rotation plate 233, for detecting a peripheral portion of the wafer W.

(Integrated Controller)

The components of the processing system 200 are connected to and controlled by a general control unit 250. The general control unit 250 controls the load-lock chambers 205a and 205b, the transfer device 209, transfer device 217 and the like, and also controls each of control units for controlling the corresponding process modules 201A to 201D.

In the processing system 200 configured as described above, a single wafer W is unloaded from the wafer cassette CR by the transfer device 217 and the orientation of the wafer is aligned in the orienter 221. Then, the wafer. W is loaded into any one of the load-lock chambers 205a and 205b and transferred to the waiting stage 206a (or 206b). Next, the wafer W in the load-lock chamber 205a (or 205a) is transferred to any one of the process modules 210A to 210D by the transfer device 209. After the film deposition, the wafer W is returned to the wafer cassette CR in a reverse sequence of the above procedure, thereby completing the process for the single wafer W.

<Process Module 201A>

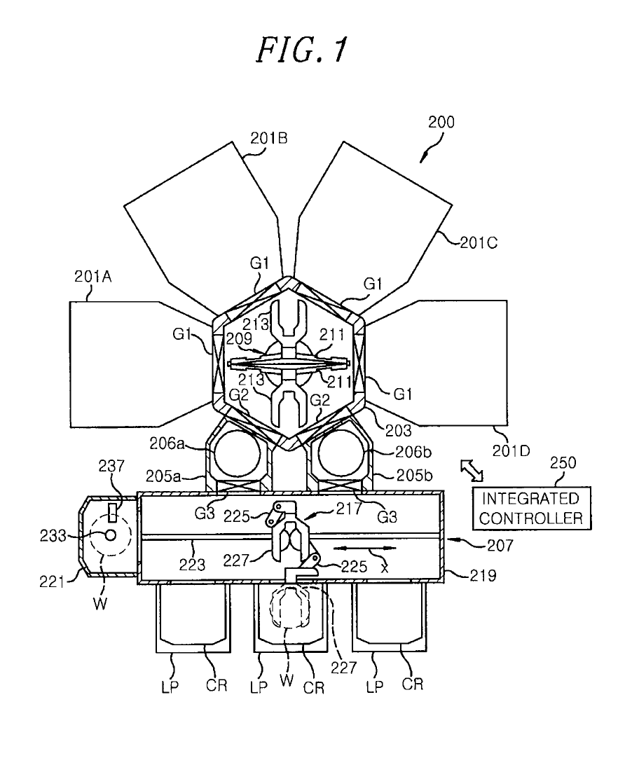

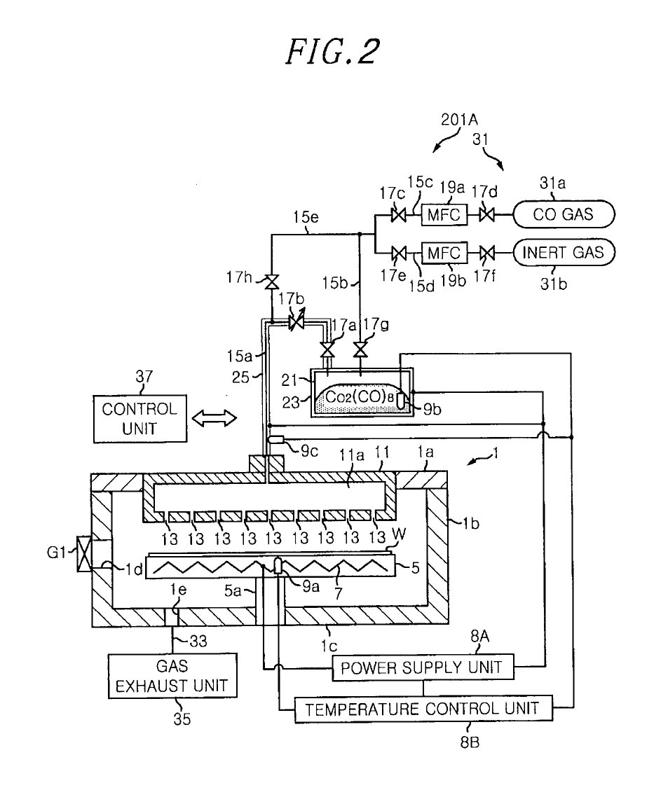

Hereinafter, the process module 201A will be described. FIG. 2 shows a schematic configuration of the process module 201A for forming a Co film on the wafer W. The process module 201A is configured as a CVD apparatus. The process module 201A mainly includes: a vacuum-evacuable processing chamber 1; a stage 5, provided in the processing chamber 1, for mounting thereon the wafer W; a heater 7 for heating the wafer W mounted on the stage 5 to be maintained at a predetermined temperature; a shower head 11 for introducing a gas into the processing chamber 1; a raw material container 21 for accommodating a cobalt precursor; a temperature control unit 23 for controlling a temperature of the cobalt precursor accommodated in the raw material container 21; a gas supply unit 31 for supplying a carrier gas for introducing the cobalt precursor into the processing chamber 1; and a gas exhaust unit 35 for depressurizing the processing chamber 1. The process module 201A can perform a film forming process for depositing a cobalt film on the wafer W.

(Processing Chamber)

The process module 201A includes a substantially cylindrical airtight processing chamber 1. The processing chamber 1 is made of, e.g., alumite-treated (anodically oxidized) aluminum or the like. The processing chamber 1 has a top plate 1a, a sidewall 1b and a bottom wall 1c.

Formed on the sidewall 1b of the processing chamber 1 are an opening 1d for loading/unloading a wafer W into and from the processing chamber 1 and a gate valve G1 for opening/closing the opening 1d. Further, O-rings (not shown) as sealing members are provided at joint portions between the components of the processing chamber 1 to ensure airtightness of the corresponding joint portions.

(Stage)

The stage 5 for horizontally supporting the wafer W is provided in the processing chamber 1. The stage 5 is supported by a cylindrical supporting member 5a. Although it is not illustrated, a plurality of lift pins for supporting and vertically moving the wafer W is provided at the stage 5 so as to be projected and retracted with respect to the substrate mounting surface of the stage 5. The lift pins are configured to be displaced vertically by an elevation mechanism and the wafer W is transferred between the lift pins and a transfer device (not shown) at elevated positions.

The heater 7 as a heating unit for heating the wafer W is embedded in the stage 5.

The heater 7 is a resistance heater which is powered by a power supply unit 8A and heats the wafer W to be maintained at a predetermined temperature. Further, the stage 5 is provided with a thermocouple 9a serving as a temperature measurement unit, so that the temperature of the stage 5 can be measured in real time. Unless particularly specified, the heating temperature of the wafer W or the processing temperature indicates the measured temperature of the stage 5. The heating unit for heating the wafer W is not limited to the resistance heater, and may be, e.g., a lamp heater.

(Shower Head)

The shower head 11 for introducing a gas such as a film forming material gas, a carrier gas or the like into the processing chamber 1 is provided at the top plate 1a of the processing chamber 1. The shower head 11 has therein a gas diffusion space 11a. A plurality of gas injection holes 13 is formed at the bottom surface of the shower head 11. The gas diffusion space 11a communicates with the gas injection holes 13. A gas supply line 15a communicating with the gas diffusion space 11a is connected to a central portion of the shower head 11.

(Raw Material Container)

The raw material container 21 accommodates therein a cobalt precursor, e.g., solid dicobalt octacarbonyl [Co₂(CO)₈]. The raw material container 21 has a temperature control unit 23 such as a jacket type heat exchanger or the like. The temperature control unit 23 is connected to the power supply unit 8A and maintains a temperature of Co₂(CO)₈ accommodated in the raw material container 21 within a range from about a room temperature (about 20° C.) to about 45° C., so that Co₂(CO)₈ can be vaporized. Further, a thermocouple 9b for measuring a temperature in the raw material container 21 in real time is provided in the raw material container 21. The cobalt precursor is not particularly limited to Co₂(CO)₈, and may be any cobalt compound which can be used as a cobalt precursor in a CVD method.

The gas supply lines 15a and 15b are connected to the raw material container 21.

As described above, the gas supply line 15a is connected to the gas diffusion space 11a of the shower head 11. The gas supply line 15a has a temperature control unit such as a jacket type heat exchanger or the like. Further, a thermocouple 9c is provided in the gas supply line 15a, so that a temperature in the gas supply line 15a can be measured in real time. The temperature control unit 25 is electrically connected to the power supply unit 8A, so that a temperature of Co₂(CO)₈ supplied to the shower head 11 through the gas supply line 15a is controlled to be maintained at a predetermined level higher than or equal to a vaporization temperature and lower than a decomposition start temperature (about 45° C.) based on the information of the temperature measured by the thermocouple 9c. Besides, a valve 17a and an opening degree control valve 17b are provided in the gas supply line 15a.

(Gas Supply Source)

The gas supply unit 31 includes a CO gas supply source 31a for supplying a CO gas, and an inert gas supply source 31b for supplying an inert gas, e.g., Ar, N₂ or the like. The CO gas and the inert gas are used as the carrier gas for carrying Co₂(CO)₈ vaporized in the raw material container 21 into the processing chamber 1. The CO gas has a function of suppressing decomposition of vaporized Co₂(CO)₈, and thus is preferably used as a part of the carrier gas. The decomposition of Co₂(CO)₈ results in generation of CO. Thus, the decomposition of Co₂(CO)₈ in the raw material container 21 can be suppressed by increasing CO concentration in the raw material container 21 by supplying CO thereinto. Further, the CO gas alone can be used as the carrier gas. In that case, an inert gas may not be used. Although it is not illustrated, the gas supply unit 31 may include, in addition to the CO gas supply source 31a and the inert gas supply source 31b, a supply source of a cleaning gas for cleaning the inside of the processing chamber 1, a supply source of a purge gas for purging the processing chamber 1, or the like.

A gas supply line 15c is connected to the CO gas supply source 31a. An MFC (mass flow controller) 19a and valves 17c and 17d disposed at an upstream side and a downstream side thereof are provided in the gas supply line 15c. A gas supply line 15d is connected to the inert gas supply source 31b. An MFC (mass flow controller) 19b and valves 17e and 17f disposed at an upstream side and a downstream side thereof are provided in the gas supply line 15d. The gas supply lines 15c and 15d are joined together to become a gas supply line 15b, and the gas supply line 15b is connected to the raw material container 21. A valve 17g is provided in the gas supply line 15b. A gas supply line 15e is branched from the gas supply line 15b. The gas supply line 15e is a bypass line directly connected from the gas supply line 15b to the gas supply line 15a without passing through the raw material container 21. The gas supply line 15e is used when the inert gas from the inert gas supply source 31b is introduced, as a purge gas, into the processing chamber 1. A valve 17h is provided in the gas supply line 15e.

In the process module 201A, the CO gas from the CO gas supply source 31a and/or the inert gas from the inert gas supply source 31b are/is introduced into the raw material container 21 through the gas supply lines 15c, 15d and 15b. Further, Co₂ (CO)₈ vaporized in raw material container 21 at a temperature controlled by the temperature control unit 23 is supplied at a flow rate controlled by the opening degree control valve 17b into the gas diffusion space 11a of the shower head 11 through the gas supply line 15a while using the CO gas and/or the inert gas as the carrier gas. The temperature of Co₂(CO)₈ supplied to the shower head 11 through the gas supply line 15a is controlled to be maintained at a predetermined level higher than or equal to the vaporization temperature and lower than the decomposition start temperature by the temperature control unit 25. Then, Co₂(CO)₈ is injected through the gas injection holes 13 toward the wafer W on the stage 5 in the processing chamber 1. In the process module 201A, Co₂(CO)₈ which is easily decomposed is introduced into the processing chamber 1 at a precisely controlled temperature.

A gas exhaust port 1e is formed at the bottom wall 1c of the processing chamber 1. The gas exhaust port 1e is connected to a gas exhaust line 33, and the gas exhaust line 33 is connected to a gas exhaust unit 35. The gas exhaust unit 35 has, e.g., a pressure control valve, a vacuum pump or the like (all not shown), and thus can exhaust the processing chamber 1 to vacuum while controlling the exhaust rate.

(Control System)

Hereinafter, a control system for performing various processes in the process module 201A will be described. The process module 201A includes a temperature control unit 8B for controlling an output of the power supply unit 8A. The power supply unit 8A, the thermocouples 9a, 9b and 9c, and the temperature control units 23 and 25 are connected to the temperature control unit 8B such that signals can be exchanged therebetween. The temperature control unit 8B sends a control signal to the power supply unit 8A by feedback control based on the information on the temperatures measured by the thermocouples 9a to 9c, and controls outputs to the heater 7 and the temperature control units 23 and 25.

Further, each of end devices (e.g., the MFCs 19a and 19b, the gas exhaust unit 35 and the like) included in the process module 201A and the temperature control unit 8B are connected to and controlled by a control unit 37. Although it is not illustrated, the control unit 37 includes a controller having, e.g., a CPU, a user interface connected to the controller, and a storage unit. The user interface includes a keyboard or a touch panel through which a user inputs commands to manage the process module 201A, a display for displaying a visualized operation status of the process module 201A1, and the like.

The storage unit stores therein control programs (software) for realizing various processes performed in the process module 201A under the control of the controller, or recipes including process condition data and the like. If necessary, any control program or recipe is read out from the storage part and executed by the controller in accordance with an instruction from the user interface or the like. Accordingly, a desired process is performed in the processing chamber 1 under the control of the controller. The control programs or the recipes such as process condition data can be used by installing the control programs or the recipes stored in a computer-readable storage medium in the storage unit. As for the computer-readable storage medium, it is possible to use, e.g., a CD-ROM, a hard disc, a flexible disc, a flash memory, a DVD or the like. It is also possible to use the control programs or the recipes transmitted from another apparatus through, e.g., a dedicated line.

In the process module 201A configured as described above, a process for forming a cobalt film is performed by a CVD method under the control of the control unit 37.

<Process Module 201B>

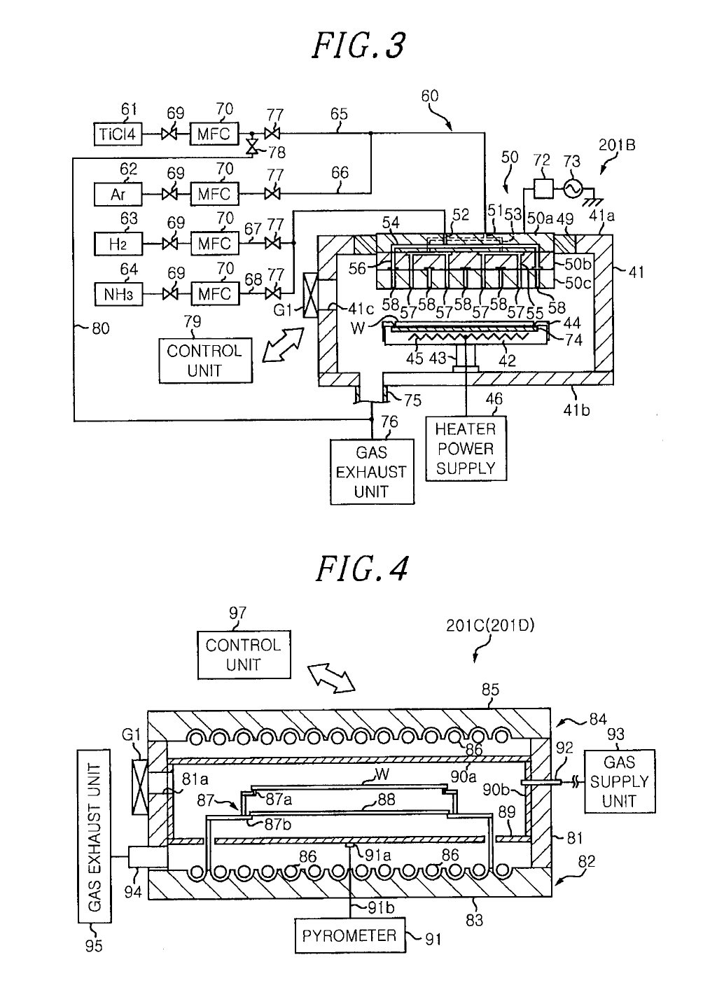

Hereinafter, a process module 201B will be described. FIG. 3 is a schematic cross sectional view of the process module 201B for forming a Ti film.

(Processing Chamber)

The process module 201B includes a substantially cylindrical airtight processing chamber 41 where a stage 42 for horizontally supporting a wafer W as a substrate to be processed is supported by a cylindrical supporting member 43. A gate valve G1 is installed at a side of the processing chamber 41 to transfer the wafer W between the processing chamber 41 and the vacuum side transfer chamber 203. By opening the gate valve G1, the wafer W can be transferred between the processing chamber 41 and the vacuum side transfer chamber 203.

(Stage)

The stage 42 is made of ceramic, e.g., AlN or the like. A guide ring 44 for guiding the wafer W is provided at an outer peripheral portion of the stage 42. The guide ring 44 also has a function of focusing a plasma. A resistance heater 45 made of molybdenum, tungsten wire or the like is embedded in the stage 42. The heater 45 is powered by the heater power supply 46 and heats the wafer W as a substrate to be processed to be maintained at a predetermined temperature. The wafer W is transferred while being raised by three lift pins (not shown) capable of projecting from and retracting into the stage 42.

(Shower Head)

A shower head 50 is provided at a top wall 41a of the processing chamber 41 via an insulating member 49. The shower head 50 includes an upper block body 50a, an intermediate block body 50b, and a lower block body 50c. Further, gas injection holes 57 and 58 are alternately formed in the lower block body 50c. A first gas inlet port 51 and a second gas inlet port 52 are formed in the top surface of the upper block body 50a.

In the upper block body 50a, a plurality of gas channels 53 is branched from the first gas inlet port 51. Gas channels 55 are formed in the intermediate block body 50b and communicate with the gas channels 53. The gas channels 55 communicate with the gas injection holes 57 of the lower block body 50c. In the upper block body 50a, a plurality of gas channels 54 is branched from the second gas inlet port 52. Gas channels 56 are formed in the intermediate block body 50b and communicate with the gas channels 54. The gas channels 56 communicate with the gas injection holes 58 of the lower block body 50c. The first and the second gas inlet port 51 and 52 are connected to the gas lines of a gas supply unit 60.

(Gas Supply Unit)

The gas supply unit 60 includes a TiCl₄ gas supply source 61 for supplying TiCl₄ gas as a Ti-containing gas, an Ar gas supply source 62 for supplying Ar gas as a plasma gas, an H₂ gas supply source 63 for supplying H₂ gas as a reduction gas, an NH₃ gas supply source 64 for supplying NH₃ gas. Gas lines 65, 66, 67 and 68 are connected to the TiCl₄ gas supply source 61, the Ar gas supply source 62, the H₂ gas supply source 63, and the NH₃ gas supply source 64, respectively. Further, valves 69 and 77 and a mass flow controller 70 are installed in each of the gas lines. The gas line 65 extending from the TiCl₄ gas supply source 61 is connected to a gas line 80 connected to the gas exhaust unit 76 via the valve 78.

The gas line 65 extending from the TiCl₄ gas supply source 61 is connected to the first gas inlet port 51, and the gas line 66 extending from the Ar gas supply source 62 is connected to the gas line 65. In addition, the gas line 67 extending from the H₂ gas supply source 63 and the gas line 68 extending from the NH₃ gas supply source 64 are connected to the second gas inlet port 52. Therefore, during the process, the TiCl₄ gas from the TiCl₄ gas supply source 61 is supplied to the shower head 50 from the first gas inlet port 51 of the shower head 50 through the gas line 65 while using Ar gas as a carrier gas, and then is injected to the processing chamber 41 through the gas injection holes 57 via the gas channels 53 and 55. Meanwhile, the H₂ gas from the H₂ gas supply source 63 is supplied to the shower head 50 from the second gas inlet port 52 of the shower head 50 through the gas line 56, and then is injected to the processing chamber 41 through the gas injection holes 58 via the gas lines 54 and 56. That is, the shower head 50 is of a post-mix type in which TiCl₄ gas and H₂ gas are independently supplied and mixed and react with each other after they are injected. The valves or the mass flow controllers in the respective gas lines are controlled by a controller (not shown).

(High frequency Power Supply)

A high frequency power supply 73 is connected to the shower head 50 via a matching unit 72. By supplying a high frequency power from the high frequency power supply 73 to the shower head 50, the gas supplied into the processing chamber 41 via the shower head 50 is turned into a plasma, and the film forming reaction takes place. A mesh-shaped electrode 74 made by weaving, e.g., molybdenum wire or the like, is embedded in an upper portion of the stage 42 and serves as a facing electrode of the shower head 50 functioning as an electrode to which a high frequency power is supplied.

(Gas Exhaust Unit)

A gas exhaust line 75 is connected to the bottom wall 41b of the processing chamber 41, and a gas exhaust unit 76 including a vacuum pump is connected to the gas exhaust line 75. By operating the gas exhaust unit 76, the processing chamber 41 can be depressurized to a predetermined vacuum level.

(Control Unit)

Each of end devices (e.g., the heater power supply 46, the MFC 70, THE gas exhaust unit 76 and the like) included in the process module 201B is connected to and controlled by the control unit 79. Although it is not illustrated, the control unit 79 includes a controller having, e.g., a CPU, a user interface connected to the controller, and a storage unit. The configuration and the function of the control unit 79 are basically the same as those of the control unit 37 of the process module 201A. In the process module 201B, a Ti film is formed by a plasma CVD method under the control of the control unit 79.

<Process Module 201C or 201D>

FIG. 4 is a cross sectional view showing a schematic configuration of the process module 201C or 201D serving as a heat treatment apparatus. The process module 201C or 201D can be used as a RTP (rapid thermal process) apparatus capable of performing heat treatment on a thin film formed on the wafer W in a short period of time at a high temperature ranging from about 800° C. to 1000° C. under an inert gas atmosphere or a reduction gas atmosphere.

(Processing Chamber)

Referring to FIG. 4, a reference numeral 81 denotes a cylindrical processing chamber. A lower heating unit 82 is detachably arranged on the lower side of the processing chamber 81, and an upper heating unit 84 is detachably arranged on the upper side of the processing chamber 81 so as to face the lower heating unit 82. Formed on a sidewall of the processing chamber 81 is an opening 81a for loading/unloading the wafer W. A gate valve G1 is provided at the opening 81a.

(Heating Unit)

The lower heating unit 82 has a water cooling jacket 83, and a plurality of tungsten lamps 86 as a heating unit arranged on the top surface of the water cooling jacket 83. In the same manner, the upper heating unit 84 has a water cooling jacket 85 and a plurality of tungsten lamps 86 as a heating unit arranged on the bottom surface of the water cooling jacket 85. The lamp is not limited to the tungsten lamp 86, and may be, e.g., a halogen lamp, a Xe lamp, a mercury lamp or the like. The tungsten lamps 86 facing each other in the processing chamber 81 are connected to a power supply (not shown), and the heat generation amount thereof can be controlled by adjusting a power supply amount from the power supply under the control of a control unit 97.

(Support Unit)

A support unit 87 for supporting the wafer W is provided between the lower heating unit 82 and the upper heating unit 84. The support unit 87 includes wafer support pins 87a for supporting the wafer W in a processing space inside the processing chamber 81, and a liner mounting portion 87b for supporting a hot liner 88 for measuring a temperature of the wafer W during the process. Further, the support unit 87 is connected to a rotation mechanism (not shown) which rotates the support unit 87 about a vertical axis as a whole. Accordingly, the wafer W rotates at a predetermined speed during the process, thereby improving the uniformity of the heat treatment.

(Pyrometer)

A pyrometer 91 is provided below the processing chamber 81. During the heat treatment, the pyrometer 91 measures heat rays from the hot liner 88 through a port 91a and an optical fiber 91b, so that the temperature of the wafer W can be measured indirectly.

Or, the temperature of the wafer W can be measured directly.

Under the hot liner 88, a quartz member 89 is provided between the hot liner 88 and the tungsten lamps 86 of the lower heating unit 82. As illustrated, the port 91a is provided at the quartz member 89. Above the wafer W, a quartz member 90a is provided between the wafer W and the tungsten lamps 86 of the upper heating unit 84. A quartz member 90b is disposed on an inner peripheral surface of the processing chamber 81 so as to surround the wafer W. Further, lifter pins (not shown) for supporting and vertically moving the wafer W extend through the hot liner 88. The lifter pins are used for loading/unloading the wafer W.

Sealing members (not shown) are disposed between the lower heating unit 82 and the processing chamber 81 and between the upper heating unit 84 and the processing chamber 81 so as to keep the processing chamber 1 airtight.

(Gas Supply Unit)

A gas supply unit 93 connected to a gas inlet line 92 is provided at a side of the processing chamber 81. Hence, an inert gas, e.g., N₂ gas or the like, or a reduction gas, e.g., H₂ gas or the like, can be introduced into the processing space inside the processing chamber 81 at a flow rate controlled by a flow rate control unit (not shown).

(Gas Exhaust Unit)

A gas exhaust line 94 is connected to a lower portion of the processing chamber 81. The processing chamber 81 can be depressurized by a gas exhaust unit 95 having a vacuum pump or the like (not shown).

(Control Unit)

Each of end devices (e.g., the lower heating unit 82, the upper heating unit 84, the gas supply unit 93, the gas exhaust unit 95 and the like) included in the process module 201C or 201D is connected to and controlled by the control unit 97. Although it is not illustrated, the control unit 97 includes a controller having, e.g., a CPU, a user interface connected to the controller, and a storage unit. The configuration and the function of the control unit 97 are basically the same as those of the control unit 37 of the process module 201A. In the process module 201C or 201D, heat treatment is performed on a Ti film and a Co film under the control of the control unit 97.

<Film Forming Method>

Hereinafter, a method for forming a thin film containing Co₃Ti alloy which is performed by the processing system 200 will be specifically described. Here, TiCl₄ is used as a titanium precursor, and cobalt carbonyl Co₂ (CO)₈ is used as a cobalt precursor. Even in the case of using another film forming material, the following sequences and conditions can be correspondingly applied.

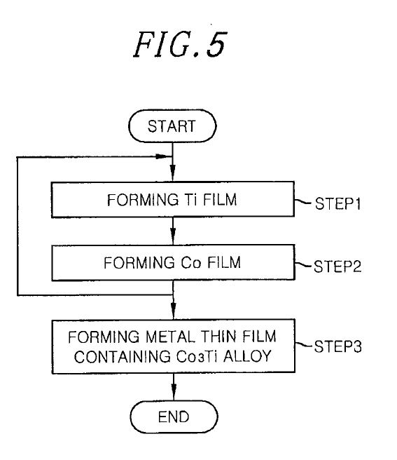

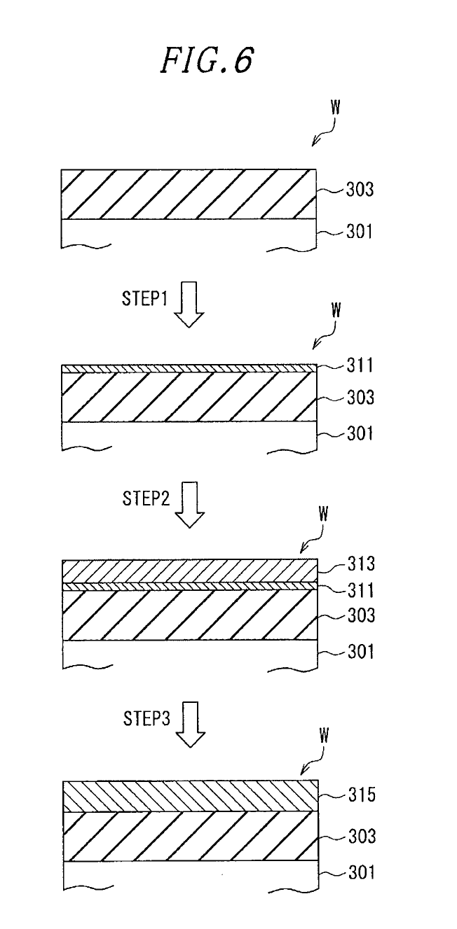

FIG. 5 is a flowchart showing an example of a sequence of the film forming method in accordance with the first embodiment of the present invention. FIG. 6 is a fragmentary cross sectional view of a wafer surface for explaining main processes of the film forming method of the present embodiment. This film forming method may includes the steps of: loading a wafer W into the process module 201B and forming a Ti film (step 1) on the wafer W; loading the wafer W having the Ti film formed thereon into the process module 201A and forming a Co film on the Ti film (step 2); and loading the wafer W into the process modules 201C or 201D and forming a thin film containing Co₃Ti alloy by performing heat treatment on the Ti film and the Co film (step 3).

(Step 1)

In step 1, a Ti film is formed by a CVD method. First, the temperature and the pressure in the processing chamber of the process module 201B are controlled to be maintained at predetermined levels, respectively, and a pre-coating process of the Ti film is performed in the processing chamber 41. Next, NH₃ gas is introduced into the processing chamber 41 and a plasma thereof is generated, so that the pre-coated Ti film is nitrided and stabilized. Thereafter, the gate valve G1 is opened, and the wafer W is loaded into the processing chamber 41 of the process module 201B by the transfer device 209 of the vacuum side transfer chamber 203 and mounted on the stage 42. Here, as shown in FIG. 6, the wafer W has an underlying film 301 formed thereon and an insulating film 303 formed on the underlying film 301. Although it is not shown, predetermined irregular patterns or openings (through holes or recesses such as trenches or the like) may be formed on the insulating film 303. Besides, an insulating film, a semiconductor film, a conductor film or the like may be formed on the wafer W. The insulating film 303 is an interlayer insulating film of a multi-layer wiring structure, for example, and the openings serve as wiring grooves or via holes. As for the insulating film 303, it is possible to use a low-k film, e.g., SiO₂, SiN, SiCOH, SiOF, CF_{q} (q being positive integers), BSG, HSQ, porous silica, SiOC, MSQ, porous MSQ, porous SiCOH or the like.

Next, the wafer W is heated by the heater 45 while exhausting the processing chamber 41 by the gas exhaust unit 76. H₂ gas is introduced into the processing chamber 41 at a flow rate ranging from, e.g., about 100 mL/min (sccm) to 5000 mL/min (sccm), and Ar gas is introduced into the processing chamber 41 at a flow rate ranging from, e.g., about 100 mL/min (sccm) to 2000 mL/min (sccm). Then, the pressure in the processing chamber 41 is controlled to be maintained within a range from, e.g., about 10 Pa to 1000 Pa while retaining Ar gas and H₂ gas, and TiCl₄ gas is introduced into the processing chamber 41 at a flow rate ranging from, e.g., about 1 mL/min (sccm) to 30 mL/min (sccm), thereby performing a pre-flow process. The heating temperature (stage temperature) of the wafer W is maintained at a level within a range from, e.g., about 500° C. to 750° C., by the heater 45. A high frequency power ranging from about 300 W to 1000 W having a frequency within a range from about 300 kHz to 1 MHz is supplied from the high frequency power supply 73 to the shower head 50. Accordingly, a plasma is generated in the processing chamber 41, and the Ti film 311 is formed by the plasma.

(Step 2)

In step 2, a Co film 313 is formed on the Ti film 311 by a thermal CVD method.

The wafer W having the Ti film 311 formed thereon is transferred from the process module 201B to the stage 5 of the process module 201A by the transfer device 209 of the vacuum side transfer chamber 203.

Specifically, the gate valve G1 is opened, and the wafer W is loaded into the processing chamber 1 through the opening 1d and transferred to lift pins (not shown) of the stage 5. Then, the wafer W is mounted on the stage 5 by lowering the lift pins. Thereafter, the pressure in the processing chamber 1 and the temperature of the wafer W are adjusted. Specifically, the temperature of the wafer W is preferably set to be higher than or equal to about 100° C. and lower than or equal to about 300° C. Next, the gate valve G1 is closed, and the processing chamber 1 is exhausted to a predetermined vacuum level by operating the gas exhaust unit 35. The pressure at this time is preferably within the range from about 1.3 Pa to 1333 Pa, for example.

The Co film 313 is formed by a CVD method on the Ti film 311 formed on the insulating film 303. In this step, the temperature of the raw material container 21 is controlled to be maintained within a range from, e.g., a room temperature to about 45° C., by the temperature control unit 23, so that Co₂(CO)₈ as a film forming material is vaporized. Then, in a state where the valve 17h is closed and the valves 17a and 17g are opened, the valves 17c and 17d and/or the valves 17e and 17f are opened. Next, the CO gas from the CO gas supply source 31a and/or the inert gas from the inert gas supply source 31b are/is introduced, as the carrier gas, into the raw material container 21 through the gas supply lines 15c and/or 15d, and 15b at the flow rates controlled by the mass flow controllers 19a and/or 19b. In that case, the total flow rate of the CO gas and/or the inert gas is preferably in the range from, e.g., about 300 mL/min (sccm) to 700 mL/min (sccm).

The vaporized Co₂(CO)₈ is supplied by the carrier gas from the raw material container 21 to the processing chamber 1 through the gas supply line 15a. In that case, the flow rate of the gaseous mixture of Co₂ (CO)₈ and the carrier gas is preferably in the range between, e.g., about 100 mL/min (sccm) and 1000 mL/min (sccm). At this time, the temperatures of the raw material container 21 and the lines 15a are controlled to be higher than or equal to the vaporization temperature of Co₂(CO)₈ and lower than the decomposition start temperature of Co₂(CO)₈ by the temperature control units 23 and 25. Thereafter, the gaseous mixture of Co₂ (CO)₈ and the carrier gas is supplied to the reaction space inside the processing chamber 1 through the gas injection holes 13 of the shower head 11. Co₂(CO)₈ is thermally decomposed in the reaction space inside the processing chamber 1. Accordingly, the Co film 313 can be formed on the Ti film 311 formed on the surface of the wafer W by a CVD method, as can be seen from FIG. 6.

The Co film 313 is deposited on the Ti film 311 formed on the surface of the wafer W until a predetermined film thickness is obtained. Then, the supply of the raw material is stopped, and the processing chamber 1 is exhausted to vacuum. Specifically, the valves 17a, 17g, and 17c to 17f are closed, and the supply of the CO gas from the CO gas supply source 31a and the inert gas from the inert gas supply source 31b is stopped. In that state, the processing chamber 1 is exhausted to vacuum by the gas exhaust unit 35. Accordingly, CO and/or Co₂(CO)₈ as an unreacted film forming material remaining in the processing chamber 1 is discharged from the processing chamber 1.

(Step 3)

In step 3, the laminated film of the Ti film 311 and the Co film 313 is modified to a metal thin film 315 containing Co₃Ti alloy by performing heat treatment. First, the wafer W having thereon the laminated film of the Ti film 311 and the Co film 313 is loaded into any one of the process modules 201C and 201D by the transfer device 209 of the vacuum side transfer chamber 203 and mounted on the wafer support unit 87 in the processing chamber 81. Next, a predetermined power is supplied from a power supply (not shown) to heating elements (not shown) of the tungsten lamps 86 of the lower heating unit 82 and the upper heating unit 84. The heating elements generate heat, and heat rays generated therefrom reach the wafer W through the quartz members 89 and 90a. Accordingly, the wafer W is rapidly heated from above and below under conditions (temperature increase rate, heating temperature, gas flow rate and the like) in accordance with a preset recipe. In order to effectively generate Co₃Ti alloy, the heating temperature of the wafer W is preferably set in the range between, e.g., about 300° C. and 1000° C., and more preferably set in the range from, e.g., about 600° C. to 900° C., based on the temperature measured by the pyrometer 91. The inert gas such as N₂ gas or the like, or the reduction gas such as H₂ gas or the like is supplied at a predetermined flow rate from the gas supply unit 93 while heating the wafer W. Further, the processing chamber 81 is exhausted through the gas exhaust line 94 by operating the gas exhaust unit 95. The oxidation of the Ti film 311, the Co film 313 and Co₃Ti alloy can be suppressed by the introduction of the reduction gas. At this time, the pressure in the processing chamber 81 is set to be in the range between, e.g., about 133.3 Pa and the atmospheric pressure. Further, it is preferable to perform the heat treatment for, e.g., about from 5 min to 60 min.

During the heat treatment, a rotary mechanism (not shown) rotates the supporting unit 87 in a horizontal direction about a vertical axis as a whole at a rotation speed ranging from, e.g., about 50 rpm to 100 rpm, to thereby rotate the wafer W. As a result, the uniformity of the amount of heat supplied to the wafer W is ensured. During the heat treatment, the temperature of the hot liner 88 is measured by the pyrometer 91, so that the temperature of the wafer W is indirectly measured. The temperature data measured by the pyrometer 91 is fed back to the process controller. When the measured temperature is different from the preset temperature of the recipe, the power supply to the tungsten lamps 86 is adjusted.

In this manner, the Ti film 311 and the Co film 313 on the wafer W are heated, and Co₃Ti alloy is generated. Further, the metal thin film 315 containing Co₃Ti alloy is formed as shown in FIG. 6.

After the heat treatment is completed, the tungsten lamps 86 of the lower heating unit 82 and the upper heating unit 84 are turned off. Further, the processing chamber 81 is exhausted through the gas exhaust line 94 while supplying a purge gas such as N₂ or the like into the processing chamber 81 through a purge port (not shown), thereby cooling the wafer W. Thereafter, the wafer W is unloaded from the processing chamber 81.

In order to effectively generate Co₃Ti alloy in accordance with steps 1 to 3, it is preferable to form the Co film 313 in step 2 such that the Co film 313 has a film thickness three times greater than that of the Ti film 311 formed in step 1. Specifically, it is preferable to set the film thickness ratio of the Ti film 311 and the Co film 313 to about 1:3. For example, in step 2, the Ti film 311 having a thickness ranging from about 1 nm to 3 nm (preferably about 2 nm) can be formed. In step 3, the Co film 313 having a thickness ranging from about 3 nm to 9 nm (preferably about 6 nm) can be formed. As shown in FIG. 5, steps 1 and 2 can be repeated multiple times.

<Metal thin film containing Co₃Ti alloy>

The metal thin film 315 containing Co₃Ti alloy formed through steps 1 to 3 contains Co₃Ti alloy, and thus has a good conductivity. The metal thin film 315 containing Co₃Ti alloy serves as a plating seed layer in the case of performing electroplating to form a Cu wiring or a Cu plug at an opening (not shown) of the insulating film 303. After the opening (not shown) of the insulating film 303 is filled with Cu, the metal thin film 315 containing Co₃Ti alloy functions as a Cu diffusion barrier film. That is, the metal thin film 315 containing Co₃Ti alloy can function as the plating seed layer and the Cu diffusion barrier film. Accordingly, the number of processes can be reduced, and it is possible to cope with the miniaturization of semiconductor devices, compared to the case of separately forming the plating seed layer and the Cu diffusion barrier film. When the metal thin film 315 containing Co₃Ti alloy is used as the plating seed layer, the barrier film made of a different material may be additionally formed. When the metal thin film 315 containing Co₃Ti alloy is used as the barrier film, the plating seed layer made of a different material may be additionally formed.

Co₃Ti alloy and Cu have a low lattice mismatch of about 0.15% therebetween. Therefore, when a Cu wiring is formed on the metal thin film 315 containing Co₃Ti alloy, an excellent adhesivity to the Cu wiring can be obtained. By forming the Cu wiring on the metal thin film 315 containing Co₃Ti alloy, stress migration or electromigration caused by thermal stress is suppressed. Accordingly, semiconductor devices having a highly reliable wiring structure can be obtained. Since the metal thin film 315 containing Co₃Ti alloy can be used as the plating seed layer and/or the barrier film, it is possible to cope with the miniaturization of semiconductor devices while ensuring the reliability thereof.

The film thickness of the metal thin film 315 containing Co₃Ti alloy is preferably in the range from, e.g., about 2 nm to 10 nm, in order to obtain the Cu diffusion barrier function while maintaining the function of the plating seed layer, and more preferably in the range from, e.g., about 5 nm or less (e.g., about 2 nm to 5 nm) in order to cope with miniaturization of the wiring patterns.

The metal thin film 315 containing Co₃Ti alloy has a high conductivity. Thus, when a metal film (not shown) of an underlying wiring such as a Cu film or the like is exposed at a bottom of an opening (not shown), the electrical connection between the metal film and the wiring embedded in the opening can be obtained though the metal thin film 315 containing Co₃Ti alloy is interposed therebetween.

The film forming method of the present embodiment may include, e.g., a step of modifying the surface of the insulating film 303, in addition to steps 1 to 3. Further, the film forming method of the present embodiment may be performed by using a Ti film forming apparatus, a Co film forming apparatus and a heat treatment apparatus without using the processing system shown in FIG. 1. Or, steps 1 to 3 may be sequentially performed in a processing chamber of a single processing apparatus.

### Second Embodiment

A film forming method in accordance with a second embodiment of the present invention will be described.

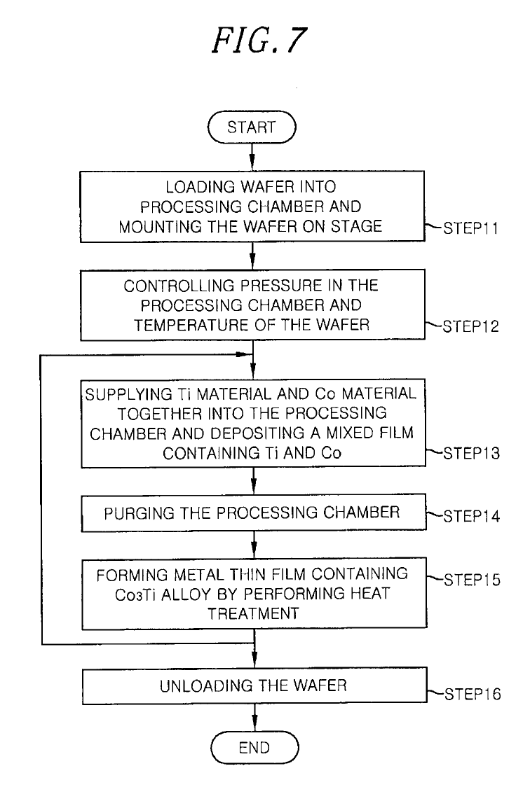

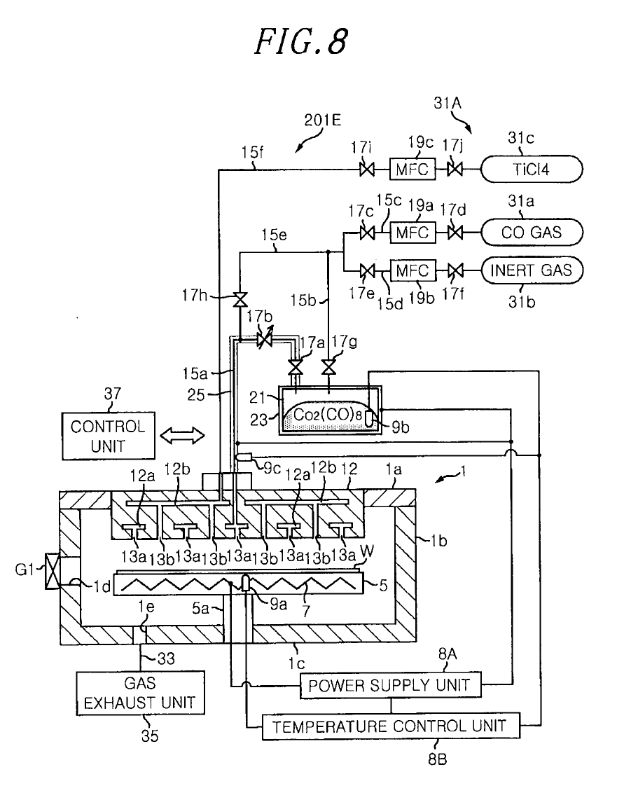

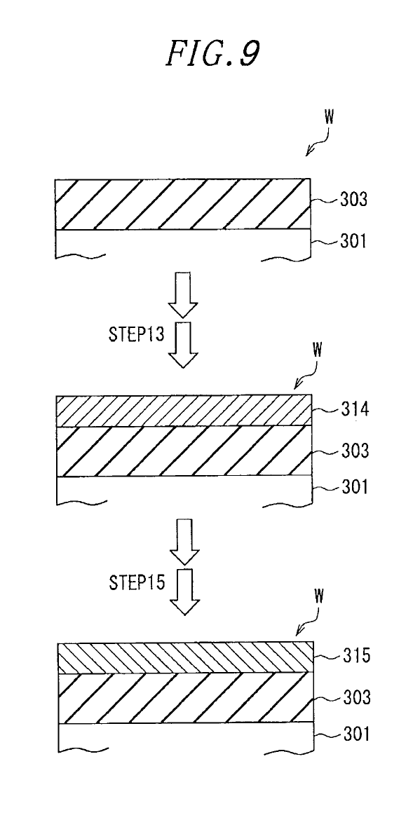

FIG. 7 is a flowchart showing an example of a sequence of the film forming method of the present embodiment. FIG. 8 is a schematic cross sectional view showing a film forming apparatus 201E which can be used for the film forming method of the present embodiment. FIG. 9 is a reference view for explaining main processes of the film forming method of the present embodiment.

<Outline of Film Forming Apparatus>

The film forming apparatus 201E shown in FIG. 8 has the same configuration as that of the film forming apparatus (process module 201A) shown in FIG. 2 except the following features. Hereinafter, only the differences will be described, and like reference numerals will designate like parts of the film forming apparatus (process module 201A) shown in FIG. 2. The film forming apparatus 201E includes a shower head 12 connected to gas supply lines 15a and 15f. The shower head 12 for introducing a gas such as a film forming material gas, a carrier gas or the like into a processing chamber 1 is provided at a top plate 1a of the processing chamber 1. The shower head 12 has therein gas diffusion spaces 12a and 12b. A plurality of gas injection holes 13a and 13b is formed in the bottom surface of the shower head 12. The gas diffusion space 12a communicates with the gas injection holes 13a, and the gas diffusion space 12b communicates with the gas injection holes 13b. The gas supply line 15a communicating with the gas diffusion space 12a and the gas supply line 15f communicating with the gas diffusion space 12b are connected to the central portion of the shower head 12. The gas supply line 15f is connected to a TiCl₄ gas supply source 31c of a gas supply unit 31A. Valves 17i and 17j and a mass flow controller (MFC) 19C are provided in the gas supply line 15f. The gas supply unit 31A may include a supply source of a reduction gas such as H2 or the like, or a supply source of a cleaning gas, in addition to a CO gas supply source 31a, an inert gas supply source 31b, and the TiCl₄ gas supply source 31c shown in FIG. 8.

<Film Forming Method>

The film forming method of the present embodiment may include steps of: loading a wafer W into the processing chamber 1 of the film forming apparatus 201E and mounting the wafer W on a stage 5 (step 11); controlling a pressure in the processing chamber 1 and a temperature of the wafer W (step 12); supplying a Ti material and a Co material together into the processing chamber 1 and depositing a mixed film containing Ti and Co on the surface of the wafer W by a CVD method (step 13); purging the processing chamber 1 by an inert gas (step 14); forming a thin film containing Co₂Ti alloy by performing heat treatment on the mixed film containing Ti and Co (step 15); and unloading the wafer W from the processing chamber 1 (step 16). In the present embodiment, the deposition of a mixed film containing Ti and Co and the heat treatment of the mixed film can be carried out.

(Step 11)

In step 11, a wafer W having, e.g., an insulating film, formed thereon is provided in the processing chamber 1 of the film forming apparatus 201E. Specifically, first, a gate valve G1 is opened, and the wafer W is loaded into the processing chamber 1 through the opening 1d and transferred to lift pins (not shown) of the stage 5. Then, the wafer W is mounted on the stage 5 by lowering the lift pins. Here, as shown in FIG. 9, the wafer W has an underlying film 301 formed thereon and an insulating film 303 laminated on the underlying film 301. The insulating film 303 is the same as the insulating film of the first embodiment.

(Step 12)

In step 12, the pressure in the processing chamber 1 and the temperature of the wafer. W are adjusted. Specifically, the gate valve G1 is closed, and the pressure in the processing chamber 1 is set to reach a predetermined vacuum level by operating the gas exhaust unit 35. The wafer W is heated to be maintained at a predetermined temperature by a heater 7.

(Step 13)

In step 13 corresponding to the film forming process, TiCl₄ and CO₂(CO)₈ are supplied into the processing chamber 1, and a mixed film 314 is deposited on the surface of the wafer W by a CVD method. In this step, the valves 17i and 17j are opened, and TiCl₄ gas is supplied from the TiCl₄ gas supply source 31c into the shower head 12 through the gas supply line 15f at a flow rate controlled by the mass flow controller 19c. The TiCl₄ gas is supplied to the reaction space inside the processing chamber 1 through the gas diffusion space 12b of the shower head 12 and the gas injection holes 13b. In that case, the flow rate of TiCl₄ gas is preferably set to be in the range from, e.g., about 30 mL/min (sccm) to 100 mL/min (sccm), in order to effectively generate CO₂(CO)₈ in the finally formed metal thin film.

CO₂(CO)₈ gas is supplied into the processing chamber 1 together with the TiCl₄ gas. Specifically, the temperature of the raw material container 21 is controlled by the temperature control unit 23 so that CO₂(CO)₈ as a film forming material is vaporized. Next, in a state where the valve 17h is closed and the valves 17a and 17g are opened, the valves 17c and 17d and/or the valves 17e and 17f are opened. Then, the CO gas from the CO gas supply source 31a and/or the inert gas from the inert gas supply source 31b are/is introduced, as the carrier gas, into the raw material container 21 through the gas supply lines 15c, 15d and 15b at the flow rates controlled by the mass flow controllers 19a and 19b. In that case, the total flow rate of the CO gas and/or the inert gas is preferably in the range between, e.g., about 300 mL/min (sccm) and 700 mL/min (sccm). The vaporized CO₂(CO)₈ is supplied from the raw material container 21 into the processing chamber 1 through the gas supply line 15a by the carrier gas. In that case, the flow rate of the gaseous mixture of CO₂(CO)₈ and the carrier gas is preferably set to be in the range from about 400 mL/min (sccm) to 1000 mL/min (sccm) in order to effectively generate CO₂(CO)₈ in the finally formed metal thin film. At this time, the temperatures of the raw material container 21 and the line 15a are controlled to be higher than or equal to the vaporization temperature of CO₂(CO)₈ and lower than the decomposition start temperature of CO₂(CO)₈ by the temperature control units 23 and 25. The gaseous mixture of CO₂(CO)₈ and the carrier gas is supplied to the reaction space inside the processing chamber 1 through the gas diffusion space 12a of the shower head 12 and the gas diffusion holes 13a.

CO₂(CO)₈ and TiCl₄ are thermally decomposed in the reaction space inside the processing chamber 1. Accordingly, the mixed film 314 can be formed on the insulating film 303 formed on the surface of the wafer W by a CVD method.

(Step 14)

Next, in step 14, a purge process is performed by introducing a purge gas into the processing chamber 1. As for the purge gas, it is possible to use Ar gas, N₂ gas or the like supplied from the inert gas supply source 31b. The purge gas can be introduced into the processing chamber 1 from the inert gas supply source 31b through the gas supply line 15d, the gas supply line 15e serving as a bypass line, the gas supply line 15a and the shower head 12. In the purge process, the purge gas is introduced into the processing chamber 1 by opening the valves 17e, 17f and 17h after stopping the supply of the carrier gas to the raw material container 21 by closing the valve 17g and exhausting the processing chamber 1 by the gas exhaust unit 35 while closing the valves 17a, 17h, 17i and 17j. The purge process of step 14 may be omitted.

(Step 15)

Thereafter, in step 15, heat treatment is performed on the mixed film 314 while introducing an inert gas into the processing chamber 1. At this time, in order to effectively generate Co₃Ti alloy in the ultimately formed metal thin film, the temperature of the heater 7 is preferably set to be in the range between about 300° C. and 1000° C. by the temperature control unit 8B, and more preferably set to be in the range from about 600° C. to 900° C.

The pressure in the processing chamber 1 is maintained at a level within a range between, e.g., about 133.3 Pa and the atmospheric pressure. The heat treatment is preferably performed for, e.g., about 5 min to 60 min. By heating the mixed film 314 formed on the wafer W, Co₃Ti alloy is generated, and the metal thin film 315 containing Co₃Ti alloy is formed. In step 15, the heat treatment can be performed while introducing a reduction gas instead of an inert gas. In that case, the oxidation of the mixed film 314 can be suppressed by the reduction gas.

(Step 16)

In step 16, the wafer W having the metal thin film containing Co₃Ti alloy formed thereon is unloaded from the processing chamber 1 in the reverse sequence of step 11.

The structure of the metal thin film 315 containing Co₃Ti alloy is the same as that of the first embodiment. In the present embodiment, in order to effectively generate Co₃Ti alloy having a small lattice mismatch with Cu in accordance with steps 11 to 16, when the mixed film 314 is formed in step 13, it is preferable to supply a Ti material and a Co material to the reaction space inside the processing chamber 1 by controlling the flow rates thereof such that the flow rate ratio of Ti:Co becomes about 1:3. Accordingly, the ratio of TI and Co contained in the mixed film 314 can be set to be about 1:3, and Co₃Ti alloy can be effectively generated. As shown in FIG. 7, steps 13 to 15 can be repeated multiple times.

The film forming method of the present embodiment may include, e.g., a step of modifying the surface of the insulating film 303, in addition to steps 11 to 16. Further, in the film forming method of the present embodiment, steps 11 to 16 can be consecutively performed by a plurality of apparatuses of the processing system 200 shown in FIG. 1. The other aspects and effects of the film forming method of the second embodiment are the same as those of the first embodiment.

In accordance with the film forming methods of the first and the second embodiment, the metal thin film 315 containing Co₃Ti alloy having a predetermined thickness can be uniformly formed on the surface of the insulating film 303. The metal thin film 315 containing Co₃Ti alloy has good electrical characteristics, good Cu diffusion barrier properties and good adhesivity to a Cu wiring.

In other words, the metal thin film 315 containing

Co₃Ti alloy formed by the film forming methods of the first and the second embodiment has a high conductivity and thus can be effectively used as a Cu plating seed layer. Further, the metal thin film 315 containing Co₃Ti alloy functions as a barrier film which effectively suppresses diffusion of Cu from a Cu wiring into the insulating film 303 while ensuring electrical connections between wirings in a semiconductor device. The metal thin film 315 containing Co₃Ti alloy contains Co₃Ti alloy having a low lattice mismatch with Cu, and thus can maintain the adhesivity to the Cu wiring. By using the metal thin film 315 containing Co₃Ti alloy formed by the film forming method of the present invention as the plating seed layer and/or the barrier film, the reliability of the semiconductor devices can be ensured.

[Example of Application of Film Forming Method to Damascene Process]

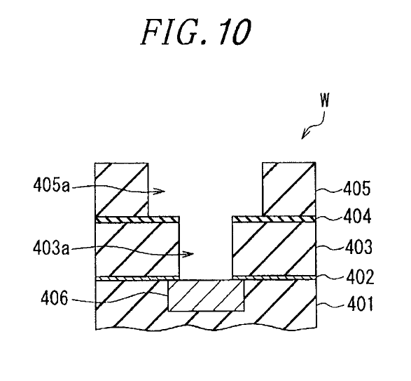

Hereinafter, the example in which the film forming methods of the first and the second embodiment are applied to a damascene process will be described with reference to FIGS. 10 to 12. FIG. 10 is a cross sectional view of principal parts of the wafer W and shows a laminated body before the formation of the metal thin film 315 containing Co₃Ti alloy. An etching stopper film 402, an interlayer insulating film 403 serving as a via layer, an etching stopper film 404 and an interlayer insulating film 405 serving as a via layer are formed in that order on an interlayer insulating film 401 serving as an underlying wiring layer. Further, an underlying wiring 406 in which Cu is embedded is formed on the interlayer insulating film 401. The etching stopper films 402 and 404 have a Cu diffusion barrier function. The interlayer insulating films 403 and 405 are low-k films formed by, e.g., a CVD method. The etching stopper films 402 and 404 are, e.g., a silicon carbide (SiC) film, a silicon nitride (SiN) film, a silicon carbide nitride (SiCN) film or the like formed by a CVD method.

As shown in FIG. 10, openings 403a and 405a are formed in a predetermined pattern in the interlayer insulating films 403 and 405. The openings 403a and 405a can be formed by etching the interlayer insulating films 403 and 405 in a predetermined pattern by using a photolithography technique. The opening 403a is a via hole, and the opening 405a is a wiring groove. The opening 403a reaches the top surface of the underlying wiring 406, and the opening 405a reaches the top surface of the etching stopper film 404.

FIG. 11 shows a state after the metal thin film 315 containing Co₃Ti alloy is formed on the laminated body shown in FIG. 10 by the method of the first or the second embodiment. The metal thin film 315 containing Co₃Ti alloy is conductive and thus functions as a plating seed layer for performing Cu plating in a post step. Further, the metal thin film 315 containing Co₃Ti alloy has a good adhesivity to Cu, and functions as a Cu diffusion barrier film. By using the metal thin film 315 containing Co₃Ti alloy, the functions of the plating seed layer and the barrier film can be realized by a single film having a thickness of, e.g., about 5 nm or less (preferably about 2 nm to 5 nm). Accordingly, the metal thin film 315 containing Co₃Ti alloy can be applied to fine wiring patterns.

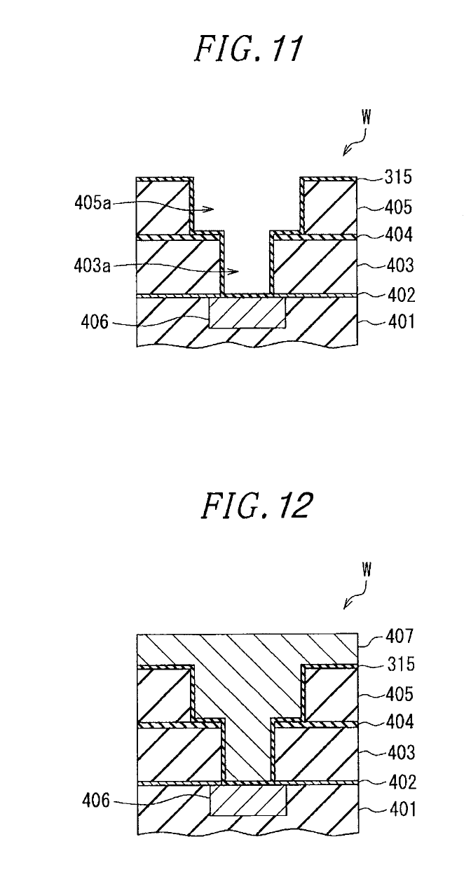

As shown in FIG. 12, the metal thin film 315 containing Co₃Ti alloy is used as a plating seed layer, and a Cu film 407 is formed by depositing Cu by electroplating to fill the openings 403a and 405a. The Cu film 407 buried in the opening 403a becomes a Cu plug, and the Cu film 407 buried in the opening 405a becomes a Cu wiring. Thereafter, the residual Cu film 407 is removed through planarization by CMP (chemical mechanical polishing). As a result, a multi-layer wiring structure having a Cu plug and a Cu wiring can be manufactured.

In the multi-layer wiring structure, the metal thin film 315 containing Co₃Ti alloy serves as a plating seed layer and has a Cu diffusion barrier function. Further, the metal thin film 315 containing Co₃Ti alloy has a good adhesivity to the Cu film 407 and suppresses stress migration or electromigration caused by thermal stress. Therefore, the generation of a delamination void at the boundary between the metal thin film 315 containing Co₃Ti alloy and the Cu film 407 can be suppressed. Further, the metal thin film 315 containing Co₃Ti alloy has a low resistivity, so that the electrical contact between the Cu film 407 and the underlying wiring 406 buried in the openings 403a and 405a can be ensured. As a result, an electronic component having a highly reliable multilayer wiring structure can be manufactured.

In the above description, the case in which the film forming method is applied to a dual damascene process has been described as an example. However, the film forming method can also be applied to a single damascene process.

While the invention has been shown and described with respect to the embodiments, the present invention can be variously modified without being limited to the above embodiments. For example, in the above embodiments, a semiconductor wafer is used as a substrate to be processed. However, the present invention is not limited thereto, and may be applied to, e.g., a glass substrate, an LCD substrate, a ceramic substrate or the like.

In the above embodiments, the Ti film and the Co film are formed by a CVD method. However, the Ti film and the Co film may be formed by, e.g., an ALD (atomic layer deposition) method or a PVD (physical vapor deposition) method. In that case, both of the Ti film and the Co film may be formed either by the ALD method or the PVD method. Moreover, the Ti film and the Co film may be formed by combination of two methods selected from the CVD method, the ALD method and the PVD method. As for the PVD method, it is possible to employ, e.g., sputtering, vacuum deposition, molecular beam deposition, ion plating, ion beam deposition or the like.

In accordance with the method for forming a metal thin film of the present embodiments as described above, a metal thin film containing Co₃Ti alloy can be formed on a substrate. The metal thin film containing Co₃Ti alloy can function as a plating seed layer and a barrier film having a high barrier property against the diffusion of Cu. Therefore, the diffusion of Cu from a Cu wiring into an insulating film can be effectively suppressed. Further, the metal thin film containing Co₃Ti alloy has a good adhesivity to Cu compared to a Co film.

Accordingly, the metal thin film containing Co₃Ti alloy formed by the metal thin film forming method can be used as a plating seed layer and a Cu diffusion barrier film. As a result, the functions of the plating seed layer and the barrier film are realized by a single layer, and it is possible to cope with miniaturization of wiring patterns. Moreover, in accordance with the method of the present invention, stress migration or electromigration caused by thermal stress is reduced, so that semiconductor devices having a highly reliable wiring structure can be manufactured. When the metal thin film containing Co₃Ti alloy formed by the method of the present invention is used as a plating seed layer and/or a barrier film, it is possible to cope with miniaturization of semiconductor devices while ensuring reliability thereof.

While the invention has been shown and described with respect to the embodiments, it will be understood by those skilled in the art that various changes and modification may be made without departing from the scope of the invention as defined in the following claims.

What is claimed is:

1. A metal thin film forming method comprising:
depositing a Ti film on an insulating film formed on a substrate;
depositing a Co film on the Ti film; and
modifying a laminated film of the Ti film and the Co film on the insulating film to a metal thin film containing Co₃Ti alloy by heating the laminated film in an inert gas atmosphere or a reduction gas atmosphere.

2. The film forming method of claim 1, wherein said depositing the Ti film and said depositing the Co film are alternately repeatedly performed.

3. The film forming method of claim 1, wherein the Ti film and the Co film have a film thickness ratio of about 1:3.

4. The film forming method of claim 1, wherein said depositing the Ti film and said depositing the Co film are performed by a CVD method or a PVD method.

5. A metal thin film forming method comprising:
depositing a mixed film containing Ti and Co on an insulating film formed on a substrate by supplying a Ti-containing material and a Co-containing material together; and
modifying the mixed film on the insulating film to a metal thin film containing Co₃Ti alloy by heating the mixed film in an inert gas atmosphere or a reduction gas atmosphere.

6. The film forming method of claim 5, wherein a ratio of Ti and Co contained in the mixed film is about 1:3.

7. The film forming method of claim 5, wherein said depositing the mixed film is performed by a CVD method or a PVD method.

8. A semiconductor device manufacturing method comprising:
forming a metal thin film containing Co₃Ti alloy on an insulating film by the metal thin film forming method described in claim 1; and
depositing a Cu film on the metal thin film containing the Co₃Ti alloy.

9. A semiconductor device manufacturing method comprising:
forming a metal thin film containing Co₃Ti alloy on an insulating film by the metal thin film forming method described in claim 5; and
depositing a Cu film on the metal thin film containing the Co₃Ti alloy.

10. A semiconductor device comprising:
an insulating film;
a metal thin film containing Co₃Ti alloy formed on the insulating film; and
a Cu wiring formed on the metal thin film containing Co₃Ti alloy.

11. The semiconductor device of claim 10, wherein the metal thin film containing Co₃Ti alloy serves as a Cu plating seed layer for forming the Cu wiring, and has a Cu barrier function for suppressing diffusion of Cu from the Cu wiring.
